(19) United States
(12) Patent Application Publication
(10) Pub. No.: US 2025/0298733 A1
(43) Pub. Date: Sep. 25, 2025

(54) MEMORY DEVICE AND METHOD FOR OPERATING THE SAME

(71) Applicant: NANYA TECHNOLOGY CORPORATION, New Taipei city (TW)

(72) Inventors: Chien Yu CHEN, New Taipei City (TW); Tsung Jui HUNG, New Taipei City (TW)

(21) Appl. No.: 18/610,833

(22) Filed: Mar. 20, 2024

(51) Int. Cl. G06F 12/02

(52) U.S. Cl. CPC G06F 12/0223

(57) ABSTRACT

A system includes a memory module and an SPD writer. The memory module includes a first memory device having a first capacity, and a serial presence detect (SPD) device configured to store data of the memory module. The SPD writer is configured to change the data according to a capacity of the memory module. The SPD writer includes a test pad configured to measure a first voltage signal generated by a controller. After the first memory device is replaced by a second memory device having a second capacity different from the first capacity, the test pad measures the first voltage signal.

### BACKGROUND

### Technical Field

The present disclosure relates to a memory technology. More particularly, the present disclosure relates to a memory system and a method for operating the memory system.

### Description of Related Art

When the capacity of the memory device is changed, the serial presence detect (SPD) data is changed (burned) correspondingly. After the SPD data is changed (burned), the SPD data is read out to verify whether the change is successful. However, the signal integrity (SI) of signals operated on the changed memory device is not verified. Thus, techniques associated with the development for overcoming the problems described above are important issues in the field.

### SUMMARY

The present disclosure provides a system includes a memory module and an SPD writer. The memory module includes a first memory device having a first capacity, and a serial presence detect (SPD) device configured to store data of the memory module. The SPD writer is configured to change the data according to a capacity of the memory module. The SPD writer includes a test pad configured to measure a first voltage signal generated by a controller. After the first memory device is replaced by a second memory device having a second capacity different from the first capacity, the test pad measures the first voltage signal.

The present disclosure also provides a method for operating a memory system. The method includes inserting a first memory device to the memory system; replacing a first memory device with a second memory device different from the first memory device; storing a first data value corresponding to the first memory device in a serial presence detect (SPD) device; changing the first data value into a second data value corresponding to the second memory device by an SPD writer; and after the first data value is changed into the second data value, measuring, by a test pad, a first voltage signal corresponding to the second memory device.

The present disclosure also provides a method for operating a memory system. The method includes inserting a first memory device to the memory system; replacing a first memory device with a second memory device different from the first memory device; storing a first data value corresponding to the first memory device in a serial presence detect (SPD) device; changing the first data value into a second data value corresponding to the second memory device; and after the first data value is changed into the second data value, measuring, by a test pad, a first voltage signal corresponding to the second memory device.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory system illustrated according to some embodiments of this disclosure.

FIG. 2 is a schematic diagram of an SPD writer illustrated according to some embodiments of this disclosure.

FIG. 3 is a schematic diagram of a test result illustrated according to some embodiments of this disclosure.

FIG. 4 is a timing diagram 400 of operations of the controller illustrated according to some embodiments of this disclosure.

FIG. 5 is a timing diagram 500 of operations of the controller illustrated according to some embodiments of this disclosure.

FIG. 6 is a flowchart of a method for operating a memory system in FIG. 1 according to some embodiments of this disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

Reference will now be made in detail to the present embodiments of the disclosure, examples of which are illustrated in the accompanying drawings. Wherever possible, the same reference numbers are used in the drawings and the description to refer to the same or like parts.

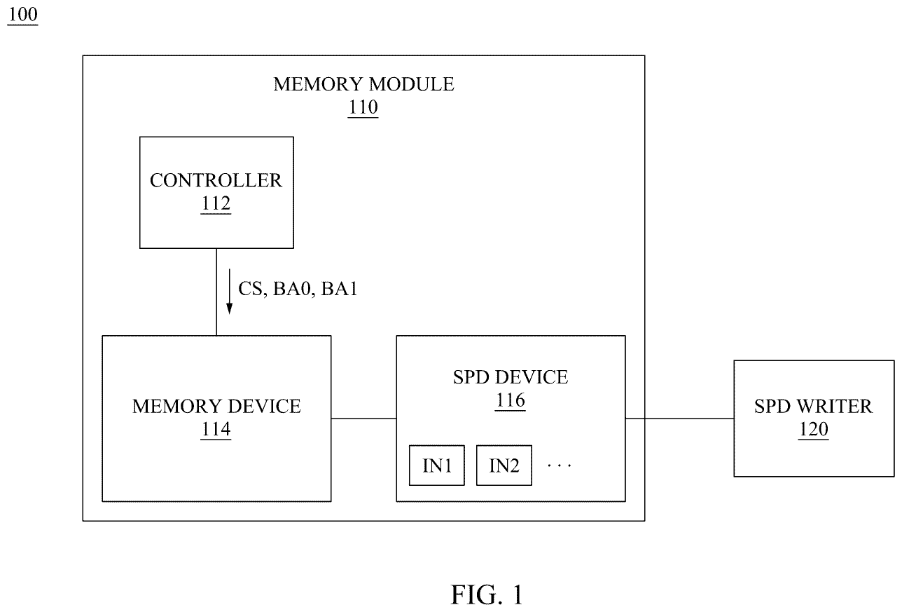

FIG. 1 is a schematic diagram of a memory system 100 illustrated according to some embodiments of this disclosure. As illustratively shown in FIG. 1, the memory system 100 includes at least a memory module 110 and a serial presence detect (SPD) writer 120. The memory module 110 is coupled to the SPD writer 120. In some embodiments, the memory module 110 is implemented as a Dual In-Line Memory Module (DIMM). The memory system 100 is implemented as a double data rate fifth-generation synchronous dynamic random-access memory (DDR5 SDRAM).

As illustratively shown in FIG. 1, the memory module 110 includes at least a controller 112, a memory device 114 and an SPD device 116. The controller 112 is coupled to the memory device 114. The memory device 114 is coupled to the SPD device 116. The SPD device 116 is coupled to the SPD writer 120. In some embodiments, the memory module 110 further includes a processor configured to perform operations on the memory device 114 and the SPD device 116.

In some embodiments, the controller 112 is configured to generate a chip select signal CS, bank signals BA0 and BA1 according to the SPD device 116 and output the chip select signal CS and the bank signals BA0 and BA1 to the memory device 114.

In some embodiments, the memory device 114 corresponds to a memory device MD1 configured to store a capacity of 8 gigabytes (GB). In some embodiments, the memory device 114 corresponds to a memory device MD2 configured to store a capacity of 16 GB. In some embodiments, the memory device 114 corresponds to a memory device configured to store a capacity other than 8 GB and 16 GB. In some embodiments, the memory device 114 is implemented as a Dynamic Random Access Memory (DRAM), such as a synchronous DRAM (SDRAM).

In some embodiments, the SPD device 116 is configured to store data representing information related to the memory module 110. Specifically, the SPD device 116 is configured to store at least data IN1 and IN2 of the memory module 110. The data IN1 corresponds to first SDRAM density and package of the memory device 114, and the data IN2 corresponds to first SDRAM bank group (BG) and banks per BG of the memory device 114. In some embodiments, the SPD device 116 is configured to store data of the memory module 110 other than the data IN1 and IN2, such as number of banks, address pins and core timing of the memory module 110. The data stored in the SPD device 116 is also referred to SPD data.

In some embodiments, the SPD writer 120 is configured to change (burn) the data IN1, IN2 and other data stored in the SPD device 116 according to the capacity of the memory device 114. Specifically, when the memory device 114 corresponds to the memory device MD1 and is then replaced by the memory device MD2, the SPD writer 120 changes the data IN1 from data value D11 to D12 and changes the data IN2 from data value D21 to D22. Similarly, when the memory device 114 corresponds to the memory device MD2 and is then replaced by the memory device MD1, the SPD writer 120 changes the data IN1 from data value D12 to data value D11 and changes the data IN2 from data value D22 to data value D21.

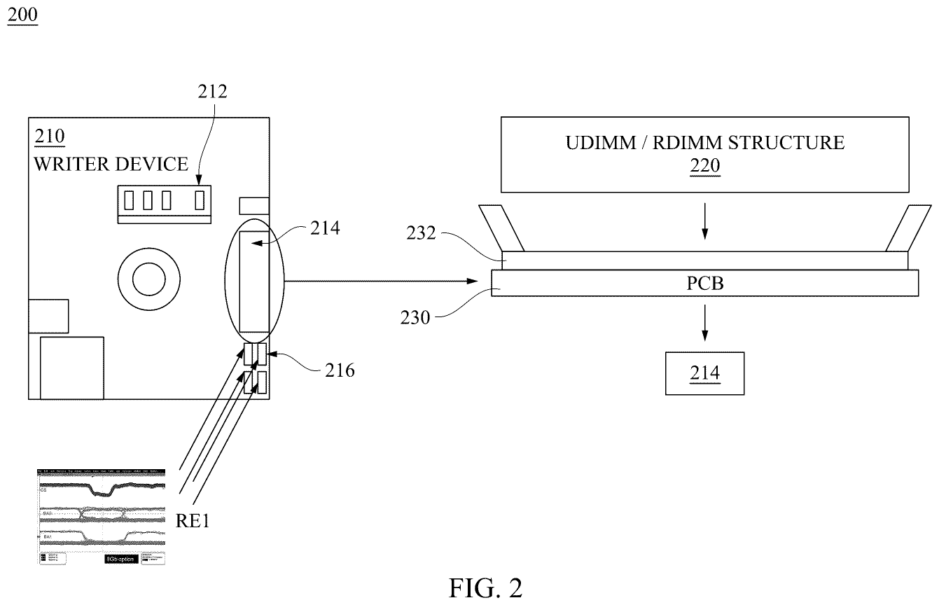

FIG. 2 is a schematic diagram of an SPD writer 200 illustrated according to some embodiments of this disclosure. Referring to FIG. 1 and FIG. 2, the SPD writer 200 is an embodiment of the SPD writer 120.

As illustratively shown in FIG. 2, the SPD writer 200 includes a writer device 210, a memory module structure 220 and a printed circuit board (PCB) 230. In some embodiments, the memory module structure 220 is implemented as an unbuffered DIMM (UDIMM) structure. In some embodiments, the memory module structure 220 is implemented as a registered DIMM (RDIMM) structure. The PCB 230 is a specially designed PCB and includes a socket 232. Referring to FIG. 1 and FIG. 2, the memory module structure 220 is an embodiment of the memory module 110.

As illustratively shown in FIG. 2, the writer device 210 includes at least a memory module structure 212, an undefined pin connector 214 and a signal integrity (SI) test pad 216. In some embodiments, the memory module structure 212 is implemented as a built-in small outline DIMM (SODIMM) structure.

In some embodiments, the PCB 230 is configured to accommodate the memory module structure 220 by inserting the memory module structure 220 to the socket 232. The PCB 230 is further configured to define the undefined pin connector 214.

In some embodiments, the SI test pad 216 is configured to verify the SI of the memory module 110 in FIG. 1. Specifically, the SI test pad 216 is configured to determine whether the controller 112 generates the chip select signal CS, the bank signals BA0 and BA1 corresponding to the capacity the memory device 114 in FIG. 1 immediately after the data IN1, IN2 and other data stored in the SPD device 116 are changed by the SPD writer 120.

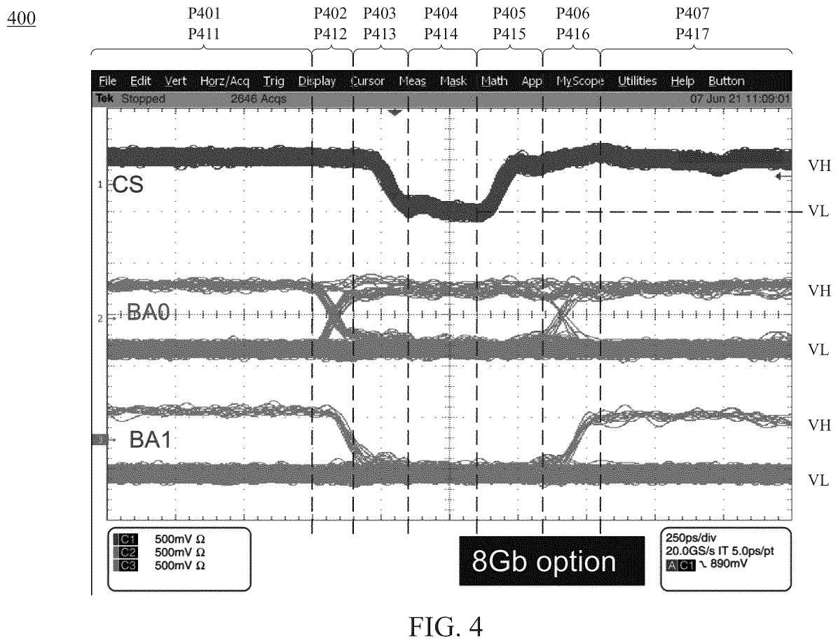

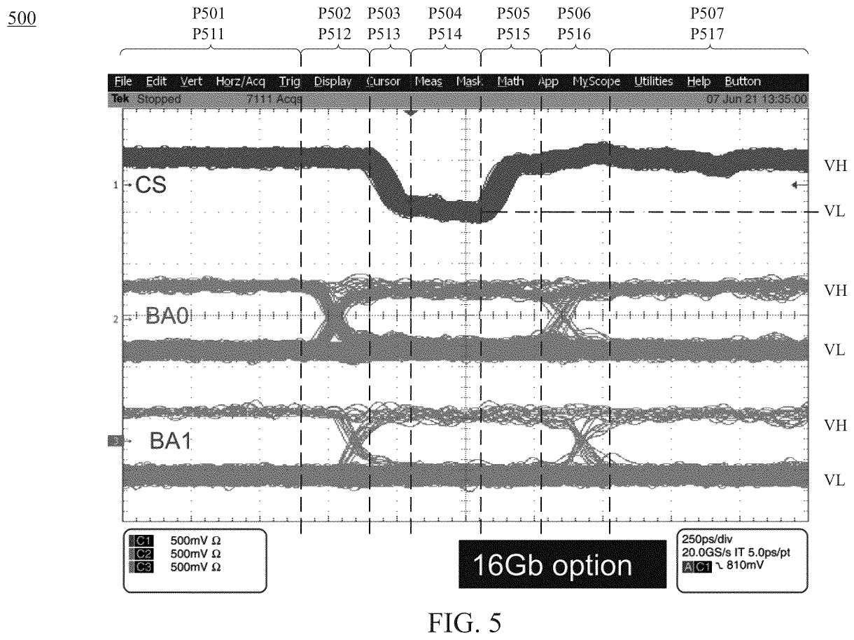

For example, the SI test pad 216 is configured to measure each of the chip select signal CS, the bank signals BA0 and BA1 and other signals generated by the controller 112 of the memory module 110 in FIG. 1, and display a timing diagram RE of at least the chip select signal CS, the bank signals BA0 and BA1 through a display device (not shown), such as timing diagrams 400 and 500 illustrated in FIG. 4 and FIG. 5, respectively.

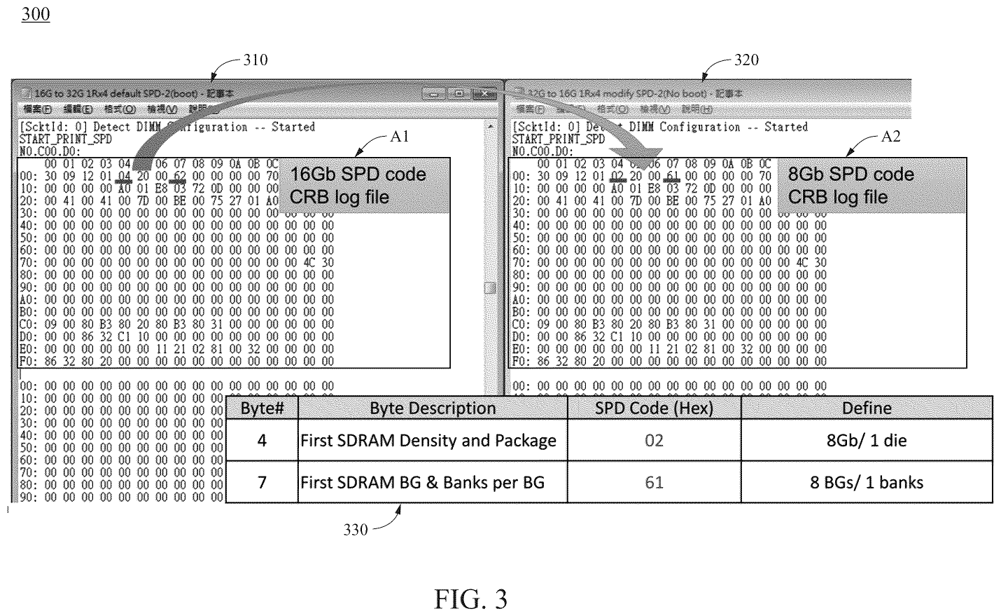

FIG. 3 is a schematic diagram of a test result 300 illustrated according to some embodiments of this disclosure. As illustratively shown in FIG. 3, the test result 300 includes files 310, 320 and a table 330. Referring to FIG. 1 to FIG. 3, each of the files 310 and 320 correspond to the data stored in the SPD device 116. In some embodiments, the file 310 corresponds to the memory device 114 with the capacity of 16 GB, and the file 320 corresponds to the memory device 114 with the capacity of 8 GB.

As illustratively shown in FIG. 3, the files 310 and 320 include arrays A1 and A2, respectively. Each of the arrays A1 and A2 includes 256 data values arranged in 16 columns in a vertical direction and 16 rows in a horizontal direction. The first column of each of the arrays A1 and A2 represents the row address of the data values, and the first row of each of the arrays A1 and A2 represents the column address of the data values.

For example, “00:” in the first column represents the first row of the data values, “10:” in the first column represents the second row of the data values, . . . , “F0:” in the first column represents the sixteenth row of the data values, “00:” in the first row represents the first column of the data values, “10:” in the first row represents the second column of the data values, . . . , “F0:” in the first row represents the sixteenth column of the data values.

In some embodiments, each of the data values in the arrays A1 and A2 corresponds to the data stored in the SPD device 116, such as the data IN1 and IN2 with the data values D11, D12, D21 and D22. The data value in the first row and the fifth column in each of the arrays A1 and A2 corresponds to the table 330, and the data value in the first row and the eighth column in each of the arrays A1 and A2 corresponds to the table 330. In some embodiments, the data values in the arrays A1 and A2 corresponds to tables other than the table 330.

Specifically, in the array A2, the data value in the first row and the fifth column is “02”, corresponds to the data value D11 of the data IN1, and corresponds to information “02” in the column of “SPD Code (Hex)” in the table 330. Accordingly, the first SDRAM density and package of the memory device 114 has the capacity of 8 GB with one die.

In the array A2, the data value in the first row and the eighth column is “61”, corresponds to the data value D21 of the data IN2, and corresponds to information “61” in the column of “SPD Code (Hex)” in the table 330. Accordingly, the first SDRAM BG and banks per BG of the memory device 114 is 8 BGs and one bank.

Similarly, in the array A1, the data value in the first row and the fifth column is “04”, corresponds to the data value D12 of the data IN2. The data value in the first row and the eighth column is “62”, corresponds to the data value D22 of the data IN2. Accordingly, the first SDRAM density and package, the first SDRAM BG and banks per BG of the memory device 114 corresponds to the situation of the memory device 114 with the capacity of 16 GB.

FIG. 4 is a timing diagram 400 of operations of the controller 112 illustrated according to some embodiments of this disclosure. As shown in FIG. 4, the timing diagram 400 includes periods P401-P407 and P411-P417 arranged continuously in order, respectively. During the periods P401-P407 and P411-P417, each of the chip select signal CS, bank signals BA0 and BA1 operates between voltage levels VH and VL. In some embodiments, the voltage level VH is higher than the voltage level VL. In some embodiments, the timing diagram 400 corresponds to operations of the memory module 110 with the memory device 114 having the capacity of 8 GB.

During the periods P401-P402, P411-P412, P406-P407 and P416-P417, the chip select signal CS is maintained at the voltage level VH. During the periods P403 and P413, the chip select signal CS is adjusted from the voltage level VH to VL. During the periods P404 and P414, the chip select signal CS is maintained at the voltage level VL. During the periods P405 and P415, the chip select signal CS is adjusted from the voltage level VL to VH.

During the periods P401, each of the bank signals BA0 and BA1 is maintained at the voltage level VH. During the periods P402, each of the bank signals BA0 and BA1 is adjusted from the voltage level VH to VL. During the periods P403-P405, each of the bank signals BA0 and BA1 is maintained at the voltage level VL. During the periods P406, each of the bank signals BA0 and BA1 is adjusted from the voltage level VL to VH. During the periods P407, each of the bank signals BA0 and BA1 is maintained at the voltage level VH.

During the periods P411, each of the bank signals BA0 and BA1 is maintained at the voltage level VL. During the periods P412, the bank signal BA0 is adjusted from the voltage level VL to VH, and the bank signal BA1 is maintained at the voltage level VL. During the periods P413-P415, the bank signals BA0 and BA1 are maintained at the voltage level VH and VL, respectively. During the periods P416, the bank signal BA0 is adjusted from the voltage level VH to VL, and the bank signal BA1 is maintained at the voltage level VL. During the periods P407, each of the bank signals BA0 and BA1 is maintained at the voltage level VL.

FIG. 5 is a timing diagram 500 of operations of the controller 112 illustrated according to some embodiments of this disclosure. As shown in FIG. 5, the timing diagram 500 includes periods P501-P507 and P511-P517 arranged continuously in order, respectively. During the periods P501-P507 and P511-P517, each of the chip select signal CS, bank signals BA0 and BA1 operates between the voltage levels VH and VL. In some embodiments, the timing diagram 500 corresponds to operations of the memory module 110 with the memory device 114 having the capacity of 16 GB.

During the periods P501-P502, P511-P512, P506-P507 and P516-P517, the chip select signal CS is maintained at the voltage level VH. During the periods P503 and P513, the chip select signal CS is adjusted from the voltage level VH to VL. During the periods P504 and P514, the chip select signal CS is maintained at the voltage level VL. During the periods P505 and P515, the chip select signal CS is adjusted from the voltage level VL to VH.

During the periods P501, each of the bank signals BA0 and BA1 is maintained at the voltage level VH. During the periods P502, each of the bank signals BA0 and BA1 is adjusted from the voltage level VH to VL. During the periods P503-P505, each of the bank signals BA0 and BA1 is maintained at the voltage level VL. During the periods P506, each of the bank signals BA0 and BA1 is adjusted from the voltage level VL to VH. During the periods P507, each of the bank signals BA0 and BA1 is maintained at the voltage level VH.

During the periods P511, each of the bank signals BA0 and BA1 is maintained at the voltage level VL. During the periods P512, each of the bank signals BA0 and BA1 is adjusted from the voltage level VL to VH. During the periods P513-P515, each of the bank signals BA0 and BA1 is maintained at the voltage level VH. During the periods P516, each of the bank signals BA0 and BA1 is adjusted from the voltage level VH to VL. During the periods P507, each of the bank signals BA0 and BA1 is maintained at the voltage level VL.

Referring to FIG. 4 and FIG. 5, each of the timing diagrams 400 and 500 is implemented by measuring the voltage level of each of the chip select signal CS, bank signals BA0 and BA1 during various operations of the controller 112 and overlapping each of the timing diagram of the chip select signal CS, bank signals BA0 and BA1 during various operations of the controller 112 together. Therefore, periods of different combinations of the periods P401-P407, P411-P417, P501-P507 and P511-P517 in the timing diagram 400 and 500 are possible.

Referring to FIG. 1 to FIG. 5, in some embodiments, the SI test pad 216 is configured to verify the SI of the memory module 110 immediately after the SPD writer changes the data IN1, IN2 and other data stored in the SPD device 116 according to the capacity of the memory device 114.

For example, in response to the capacity of the memory device 114 is 8 GB and then replaced by 16 GB, the SPD writer 120 changes the data IN1 from the data value D11 to D12 and changes the data IN2 from the data value D21 to D22, and the SI test pad 216 immediately measures each of the chip select signal CS, the bank signals BA0 and BA1 and other signals generated by the controller 112. If the data IN1 and IN2 is successfully changed to the data value D12 and D22, the display device displays the timing diagram 500.

For another example, in response to the capacity of the memory device 114 is 16 GB and then replaced by 8 GB, the SPD writer 120 changes the data IN1 from the data value D12 to D11 and changes the data IN2 from the data value D22 to D21, and the SI test pad 216 immediately measures each of the chip select signal CS, the bank signals BA0 and BA1 and other signals generated by the controller 112. If the data IN1 and IN2 is successfully changed to the data value D11 and D21, the display device displays the timing diagram 400.

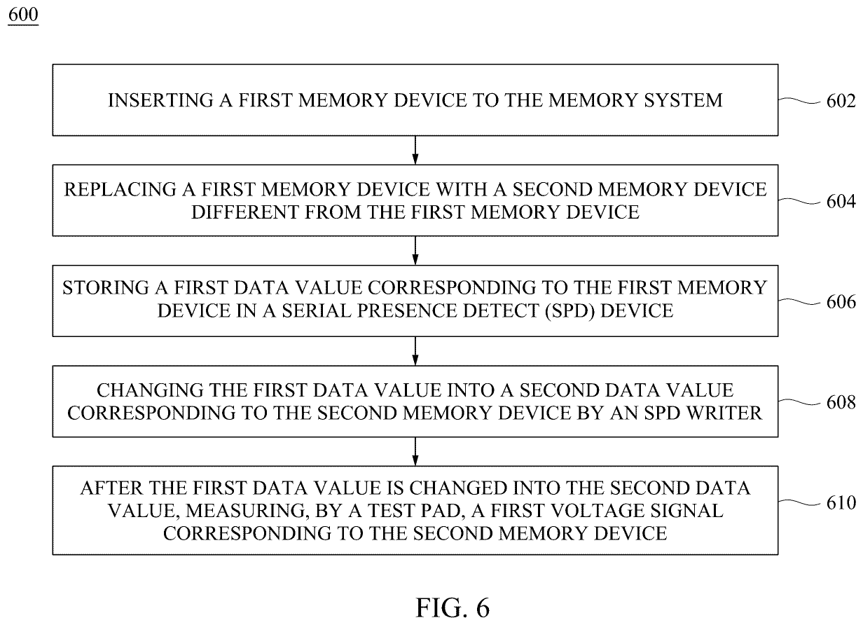

FIG. 6 is a flowchart of a method 600 for operating a memory system 100 in FIG. 1 according to some embodiments of this disclosure. In FIG. 6, method 600 includes operations 602, 604, 606, 608 and 610.

At operation 602, the memory device 114 with the capacity of 8 GB is inserted to the memory system 100.

At operation 604, the memory device 114 with the capacity of 8 GB is replaced with the memory device 114 with the capacity of 16 GB.

At operation 606, the data value D11 corresponding to the memory device 114 with the capacity of 8 GB is stored in the serial presence detect (SPD) device 116.

At operation 608, the data value D11 is changed into the data value D12 corresponding to the memory device 114 with the capacity of 16 GB by the SPD writer 120.

At operation 610, after the data value D11 is changed into the data value D12, the chip select signal CS is measured corresponding to the second memory device by the test pad 216.

In some approaches, when the capacity of the memory device is changed, the SPD data is changed (burned) correspondingly. After the SPD data is changed (burned), the SPD data is read out to verify whether the change is successful. However, the signal integrity (SI) of signals operated on the changed memory device is not verified.

Compared to the above approaches, in some embodiments of the present disclosure, after the data value D11 is changed into the data value D12, each of the chip select signal CS signals, bank signals BA0 and BA1 is measured by the test pad 216. As a result, the signal integrity (SI) of each of the chip select signal CS signals, bank signals BA0 and BA1 operated on the memory device 114 is immediately verified.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A system, comprising:
a memory module, comprising:
a first memory device having a first capacity; and
a serial presence detect (SPD) device configured to store data of the memory module; and
an SPD writer configured to change the data according to a capacity of the memory module, the SPD writer comprising:
a test pad configured to measure a first voltage signal generated by a controller,
wherein after the first memory device is replaced by a second memory device having a second capacity different from the first capacity, the test pad measures the first voltage signal.

2. The system of claim 1, wherein
the first capacity is 8 gigabytes (GB), and
the second capacity is 16 GB.

3. The system of claim 1, wherein
the data further comprises a first data value corresponding to the first memory device,
after the first memory device is replaced by the second memory device, the SPD writer changes the first data value to a second data value corresponding to the second memory device, and
the first voltage signal corresponds to the second memory device.

4. The system of claim 3, wherein
the data further comprises a third data value corresponding to the first memory device,
after the first memory device is replaced by the second memory device, the SPD writer changes the third data value to a fourth data value corresponding to the second memory device.

5. The system of claim 4, wherein
the first data value is equal to “02”, and
the second data value is equal to “04”.

6. The system of claim 5, wherein
the third data value is equal to “61”, and
the fourth data value is equal to “62”.

7. The system of claim 1, wherein
the test pad is further configured to measure a second voltage signal different from the first voltage signal generated by the controller,
after the first memory device is replaced by the second memory device, the test pad measures the second voltage signal.

8. The system of claim 7, wherein
the test pad is further configured to measure a third voltage signal different from the first voltage signal and the second voltage signal generated by the controller,
after the first memory device is replaced by the second memory device, the test pad measures the third voltage signal.

9. A method for operating a memory system, comprising:
inserting a first memory device to the memory system;
replacing a first memory device with a second memory device different from the first memory device;
storing a first data value corresponding to the first memory device in a serial presence detect (SPD) device;
changing the first data value into a second data value corresponding to the second memory device by an SPD writer; and
after the first data value is changed into the second data value, measuring, by a test pad, a first voltage signal corresponding to the second memory device.

10. The method of claim 9, wherein
the first memory device has a first capacity of 8 gigabytes (GB), and
the second memory device has a second capacity of 16 GB.

11. The method of claim 10, further comprising:
storing a third data value corresponding to the first memory device in the SPD device;
changing the third data value into a fourth data value corresponding to the second memory device by an SPD writer,
after the first data value and the third data value are changed into the second data value and the fourth data value, respectively, measuring, by the test pad, the first voltage signal.

12. The method of claim 11, wherein
the first data value is equal to “02”, and
the second data value is equal to “04”.

13. The method of claim 12, wherein
the third data value is equal to “61”, and
the fourth data value is equal to “62”.

14. The method of claim 13, further comprising:
after the first data value is changed into the second data value, measuring, by the test pad, a second voltage signal different from the first voltage signal corresponding to the second memory device, and
wherein during a first period,
the first voltage signal has a first voltage level, and
the second voltage signal has a second voltage level different from the first voltage level.

15. The method of claim 14, further comprising:
after the first data value is changed into the second data value, measuring, by the test pad, a third voltage signal different from the first voltage signal and the second voltage signal corresponding to the second memory device, and
wherein during the first period, the third voltage signal has the second voltage level.

16. A method for operating a memory system, comprising:
inserting a first memory device to the memory system;
replacing a first memory device with a second memory device different from the first memory device;
storing a first data value corresponding to the first memory device in a serial presence detect (SPD) device;
changing the first data value into a second data value corresponding to the second memory device; and
after the first data value is changed into the second data value, measuring, by a test pad, a first voltage signal corresponding to the second memory device.

17. The method of claim 16, further comprising:
storing a third data value corresponding to the first memory device in the SPD device;
changing the third data value into a fourth data value corresponding to the second memory device by an SPD writer,
after the first data value and the third data value are changed into the second data value and the fourth data value, respectively, measuring, by the test pad, the first voltage signal.

18. The method of claim 17, wherein
the first data value is equal to “02”,
the second data value is equal to “04”,
the third data value is equal to “61”, and
the fourth data value is equal to “62”.

19. The method of claim 17, further comprising:
after the first data value is changed into the second data value, measuring, by the test pad, a second voltage signal different from the first voltage signal corresponding to the second memory device, and
wherein during a first period,
the first voltage signal has a first voltage level, and
the second voltage signal has a second voltage level different from the first voltage level.

20. The method of claim 19, further comprising:
after the first data value is changed into the second data value, measuring, by the test pad, a third voltage signal different from the first voltage signal and the second voltage signal corresponding to the second memory device, and
wherein during the first period, the third voltage signal has the second voltage level.
